(19) United States
(12) Patent Application Publication
(10) Pub. No.: US 2026/0190962 A1
(43) Pub. Date: Jul. 2, 2026

(54) METHOD FOR MANUFACTURING A VIA0 STRUCTURE

(71) Applicant: Shanghai Huali Integrated Circuit Corporation, Shanghai (CN)

(72) Inventor: Binbin Zha, Shanghai (CN)

(73) Assignee: Shanghai Huali Integrated Circuit Corporation, Shanghai (CN)

(21) Appl. No.: 19/306,766

(22) Filed: Aug. 21, 2025

(30) Foreign Application Priority Data
Jan. 2, 2025 (CN) CN202510008232.X

(51) Int. Cl. H01L 21/768; H01L 21/02; H01L 21/311

(52) U.S. Cl. CPC H10W 20/082; H10P 50/283; H10P 70/27; H10W 20/057; H10W 20/062

(57) ABSTRACT

The present application discloses a method for manufacturing a via0 structure, comprising the following steps: providing an underlying structure comprising a metal zero-level layer, a first liner layer as well as a first ILD film, wherein the metal zero-level layer comprises Co. A via0 opening is formed by sequentially etching first ILD film and first liner layer in the designated via0 formation region. During the formation of the via0 opening, the fluorine-containing polymer as well as Co-damaged layer are generated. A first wet cleaning is performed to remove the Co-damaged layer from the metal zero-level layer, utilizing fluorine retained in the fluorine-containing polymer to enhance the removal efficiency. A second wet cleaning is subsequently carried out to remove the fluorine-containing polymer. Since the Co-damaged layer has already been removed, the second wet cleaning does not cause Co residue defects. Selective tungsten growth is carried out to form the via0 structure.

### CROSS REFERENCE TO RELATED APPLICATIONS

This application claims priority to Chinese patent application No. 202510008232.X, filed on Jan. 2, 2025, the disclosure of which is incorporated herein by reference in its entirety.

### TECHNICAL FIELD

The present application relates to method for manufacturing semiconductor integrated circuit, and in particular to a method for manufacturing a via0 (V0) structure.

### BACKGROUND

To reduce contact resistance, the metal zero-level (M0) layer in the middle-of-line (MOL) process has evolved from tungsten (W) contact scheme to cobalt (Co) contact scheme. Since Co is relatively reactive, a liner layer is required after the formation of the Co layer and before the formation of the first interlayer dielectric film. The liner layer covers the Co layer to provide protection.

A via0 (V0) structure needs to be formed on top of the metal zero-level (M0) layer to further connect to upper metal layer. The via0 structure is typically formed by selectively growing tungsten (W) to fill the V0 opening. However, during formation of the via0 structure, severe tungsten missing defects are often observed.

FIGS. 1A to 1D are the schematic views of the device structures at various steps in a conventional via0 (V0) manufacturing process. The conventional V0 manufacturing method includes the following steps:

As shown in FIG. 1A, a bottom structure is provided. The bottom structure includes metal zero-level (M0) layers 102, a first liner layer 103 and a first interlayer dielectric (ILD) film 104. The metal zero-level (M0) layers 102 are isolated from each other by via0 interlayer dielectric (ILD) film 101. A first liner layer 103 is formed to cover the top surfaces of both M0 layers 102 and via0 ILD film 101. A first interlayer dielectric (ILD) film 104 is formed on the top surface of the first liner layer 103.

The metal zero-level (M0) layers 102 are made of cobalt (Co). Due to the reactivity of Co, it is necessary to quickly deposit the first liner layer 103 after Co chemical-mechanical polishing (CMP), in order to protect Co. The first liner layer 103 serves as a protective layer for the Co, reducing oxidation and material loss.

Typically, the first liner layer 103 is made of silicon nitride or silicon carbide.

The first interlayer dielectric (ILD) film 104 is made of the silicon oxide or a low-k dielectric material.

As shown in FIG. 1A, the first ILD film 104 and the first liner layer 103 in the via0 formation region are sequentially etched to form a via0 opening 105.

The etching process of the first liner layer 103 is the liner removal (LRM) process. Dry etching is employed for etching the first liner layer 103 by using process gases including difluoromethane (CH₂F₂), and optionally oxygen or nitrogen.

In FIG. 1A, the dashed arrow line 106 indicates the etching process of the first liner layer 103.

Since fluorine-containing gases are used in etching process of first liner layer 103, a fluorine-containing polymer 107 is formed at the end of the process.

Meanwhile, since etching process for the via0 opening 105 involves multiple steps, plasma is used during these steps for the plasma etching. Specifically, the dry plasma etching is applied to both first interlayer dielectric (ILD) film 104 as well as first liner layer 103. The plasma bombardment during the etching process causes damage to the surface region of the metal zero-level (M0) layer 102, resulting in the formation of a cobalt damage layer 102a.

As shown in FIG. 1B, the first wet cleaning is performed to remove the part of the fluorine-containing polymer 107. Typically, the cleaning solution which is used to remove the fluorine-containing polymer 107 is a solution designated as C1000 by the applicant. FIG. 1B shows a reduction in the amount of the fluorine-containing polymer 107. The C1000 solution primarily contains certain cobalt (Co) inhibitors and is weakly alkaline.

As shown in FIG. 1C, a second wet cleaning is performed. During the second wet cleaning, deionized (DI) water is first used to etch the cobalt damage layer 102a, followed by cleaning with the C1000 solution to remove cobalt residues.

When cobalt damage layer 102a is removed using DI solution, the residual fluorine in fluorine-containing polymer 107 is used to generate hydrofluoric acid (HF), which in turn removes the cobalt damage layer 102a.

However, in actual processing, as shown in FIG. 1C, the second wet cleaning cannot completely remove cobalt residues. On the contrary, it tends to result in cobalt residue defects 108.

Subsequently, a pretreatment is performed using an alkaline solution, namely an OH pretreatment.

Thereafter, selective tungsten (W) growth is carried out to deposit a tungsten layer 1091 upward from the bottom surface of the via0 opening 105. The tungsten layer 1091 fills the via0 opening 105, thereby forming the via0 structure.

The selective tungsten (W) growth occurs only on the surfaces having metal. When cobalt residue defects 108 are present on side surfaces or outer regions of via0 opening 105, tungsten may also grow on the surfaces of the cobalt residue defects 108. As shown in FIG. 1D, the tungsten layer grown on cobalt residue defects 108 is denoted as 1092. The tungsten layer 1092 may form a cap at top of the via0 opening 105. Once opening is capped, tungsten can no longer grow inside the via0 opening 105, resulting in the formation of a void 110.

Tungsten chemical mechanical polishing (CMP) process is performed to planarize the tungsten layer 109. After the tungsten CMP process, the void 110 within the via0 opening 105 where the tungsten layer 1092 has been formed may become exposed.

FIGS. 2A to 2D are top-view images of the device structures at various steps of the conventional via0 manufacturing method. FIG. 2A is image corresponding to FIG. 1C, taken after completion of the second wet cleaning. In FIG. 2A, the first interlayer dielectric film is labeled separately as 104a, the via0 opening is labeled as 105 a, and the cobalt residue defects are labeled as 108a.

FIG. 2B is an image taken after completion of OH pretreatment. It can be observed that the cobalt residue defects 108a are not completely removed.

FIG. 2C is an image corresponding to FIG. 1D, taken after completion of selective tungsten (W) growth. In FIG. 2C, tungsten layer grown upward from bottom of via0 opening 105a is labeled separately as 1091a, and the tungsten layer grown on surface of cobalt residue defects 108a is labeled separately as 1092a.

FIG. 2D is an image taken after the completion of the tungsten chemical-mechanical polishing (CMP) process. It can be observed that, in regions where the via0 opening 105a is fully filled with tungsten layer 1091a, a normal via0 structure 109 composed of the tungsten layer 1091a is formed. However, in regions where the tungsten layer 1092a is present, via0 opening 105a results in via 109a with tungsten missing defect. The via 109a with the tungsten missing defect cannot establish the proper electrical connection, which may adversely affect product yield.

### BRIEF SUMMARY

According to some embodiments in this application, a method for manufacturing via0 structure is disclosed in the following steps:
providing a bottom structure comprising a metal zero-level (M0) layer, a first liner layer as well as a first interlayer dielectric (ILD) film, wherein the metal zero-level layers are isolated from each other by via0 ILD film, the first liner layer covers top surfaces of both the metal zero-level layer and the via0 ILD film, and the first ILD film is formed on a top surface of the first liner layer; wherein a material of the metal zero-level layer comprises cobalt (Co);
etching the first ILD film and the first liner layer in a via0 formation region to form a via0 opening, wherein etching of the first liner layer generates fluorine-containing polymer, and plasma used during the etching process causes a cobalt damage layer to form on a surface region of the metal zero-level layer;
performing first wet cleaning to remove cobalt damage layer in the metal zero-level layer, wherein a fluorine remaining in the fluorine-containing polymer is utilized to enhance the removal of the cobalt damage layer;
performing a second wet cleaning to remove fluorine-containing polymer, wherein the cobalt damage layer has been previously removed, thereby preventing formation of cobalt residue defects during the second wet cleaning; and
performing selective tungsten (W) growth to deposit a tungsten layer from a bottom surface of the via0 opening upward, such that the tungsten layer fills the via0 opening to form the via0 structure.

In some cases, the material of the first liner layer comprises silicon nitride or silicon carbide.

In some cases, material of first interlayer dielectric film comprises silicon oxide or a low-k dielectric material.

In some cases, etching the first interlayer dielectric film to form the via0 opening comprises a first dry etching process.

In some cases, etching the first interlayer dielectric film comprises performing a second wet etching process after the first dry etching process is completed.

In some cases, etching the first liner layer to form the via0 opening comprises a second dry etching process; and a process gas used in second dry etching process comprises a fluorine-containing gas.

In some cases, the process gas used in the second dry etching process further comprises oxygen or nitrogen.

In some cases, fluorine-containing gas comprises difluoromethane (CH₂F₂).

In some cases, a deionized solution is used as a cleaning solution in the first wet cleaning.

In some cases, a cleaning solution used in the second wet cleaning comprises a cobalt (Co) inhibitor and is weakly alkaline.

In some cases, the second wet cleaning is performed multiple times.

In some cases, the second wet cleaning is performed twice.

In some cases, after the second wet cleaning is completed and before the selective tungsten growth is performed, the method further comprises:
performing a pretreatment using an alkaline solution.

In some cases, after the selective tungsten growth is completed, the method further comprises:
performing a tungsten chemical-mechanical polishing (CMP) process to planarize the tungsten layer.

The present application leverages the fact that both fluorine-containing polymer and cobalt (Co) damage layer are simultaneously generated during formation of the via0 opening. Unlike the prior art, in which the cleaning process to remove the fluorine-containing polymer is performed first, followed by cleaning process to remove the Co-damaged layer, the present application changes the process sequence by performing the cleaning process for removing the Co-damaged layer first, namely the first wet cleaning. At this stage, since fluorine-containing polymer has not been removed, the fluorine contained in the polymer can be utilized to assist in removal of the Co-damaged layer. After the Co-damaged layer has been removed, a second wet cleaning process is then carried out to remove the fluorine-containing polymer. During this second wet cleaning, fluorine-containing polymer can be completely removed. Moreover, since Co-damaged layer has already been removed, and second wet cleaning does not affect the undamaged Co layer, namely the fresh Co layer, no Co residue defects will be generated during the second wet cleaning process. In other words, no Co residue defects will form on side surfaces or outer regions of via0 opening. As a result, during selective tungsten growth process, tungsten can reliably grow upward from top surface of the exposed metal zero-level layer at the bottom of the via0 opening. This prevents the tungsten layer from growing on the surfaces of Co residue defects in other regions, thereby avoiding the formation of a cap at the top of via0 opening and the occurrence of tungsten missing defects on right side. As a result, the tungsten layer can completely fill the via0 opening from the bottom up, thereby forming a high-quality via0 and ultimately improving device performance and yield.

### BRIEF DESCRIPTION OF THE DRAWINGS

The present application will be further described in detail below in conjunction with the accompanying drawings and specific embodiments:

FIGS. 1A to 1D are schematic diagrams of the device structures at various steps in a conventional method for manufacturing a via0 structure;

FIGS. 2A to 2D are the top-view photographs of the device at various steps in the conventional method for manufacturing a via0 structure;

FIG. 3 is a flow chart of the method for manufacturing a via0 structure according to an embodiment of the present application;

FIGS. 4A to 4D are schematic diagrams of device structures at various steps in the method for manufacturing a via0 structure according to embodiment of the present application.

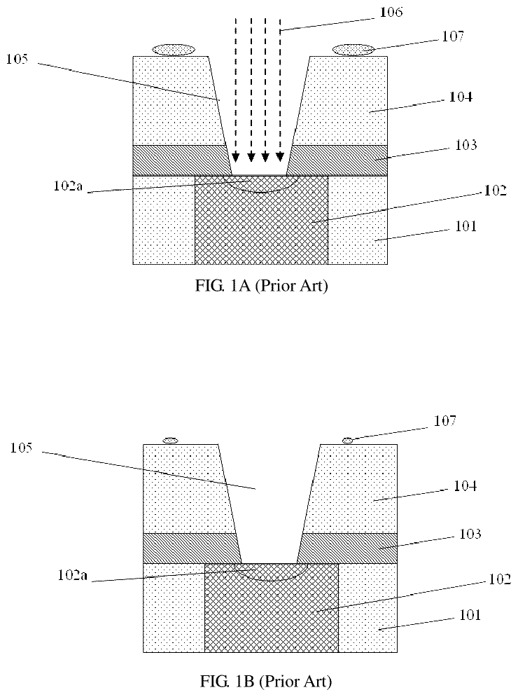

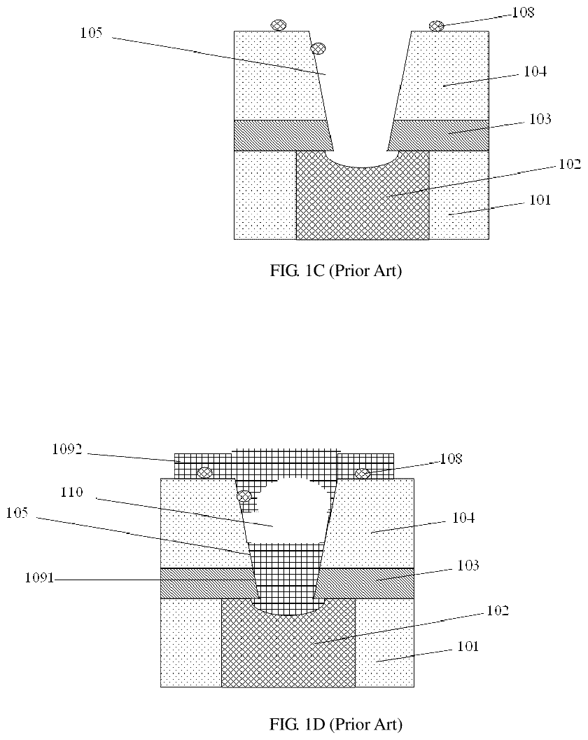

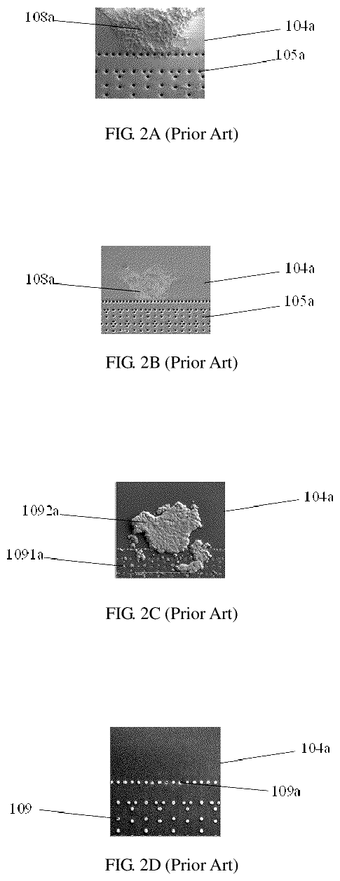

### DETAILED DESCRIPTION OF THE DISCLOSURE

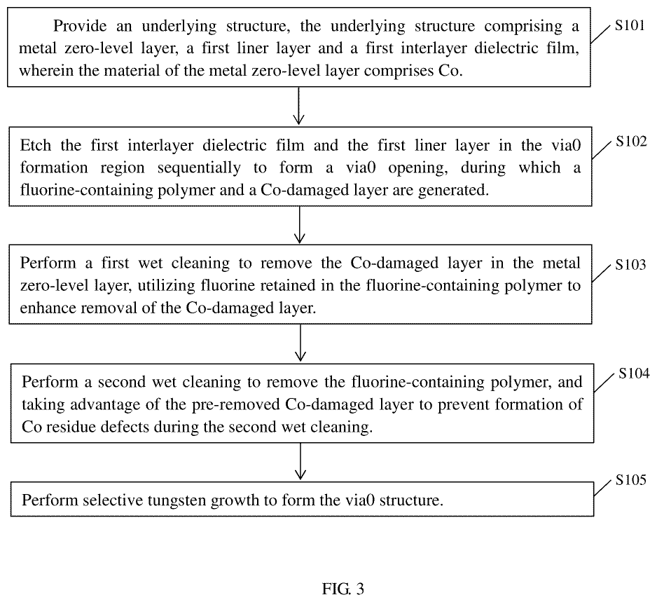

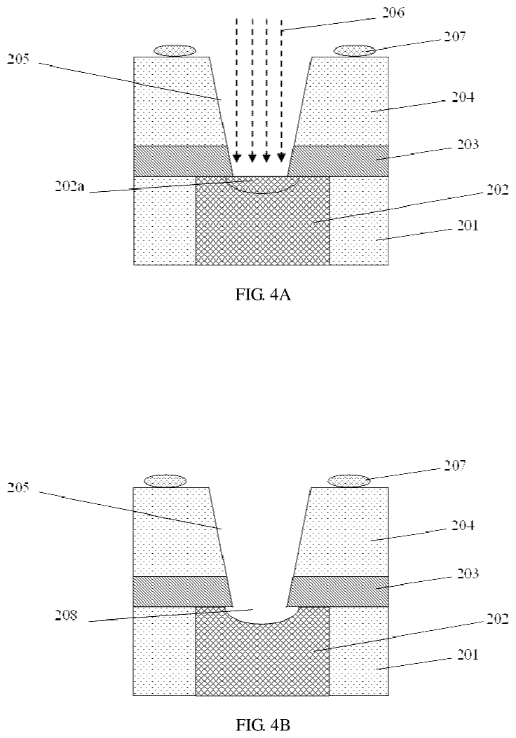

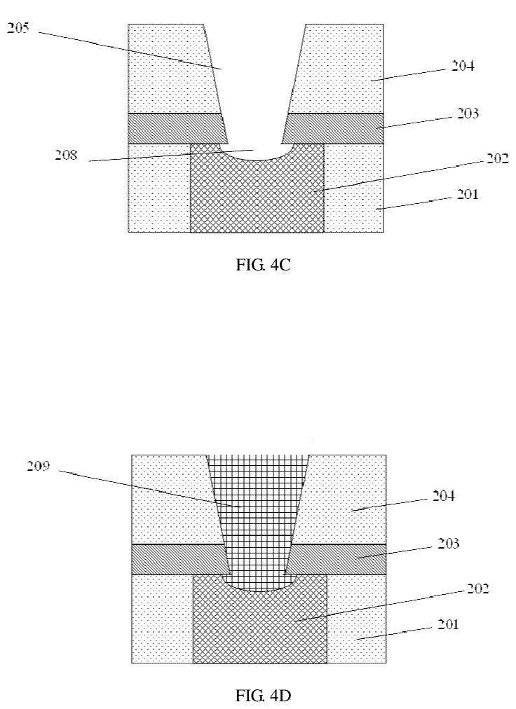

As shown in FIG. 3, a flow chart of the method for manufacturing a via0 structure according to the embodiment of the present application is provided. FIG. 4A to FIG. 4D are the cross-sectional schematic diagrams of the device structures at various steps of the method for manufacturing the via0 structure according to embodiment of present application. The method for manufacturing the via0 structure of the present embodiment includes the following steps:

Step S101: As shown in FIG. 4A, a base structure is provided. The base structure comprises a metal zero-level layer 202, a first liner layer 203 and a first interlayer dielectric (ILD) film 204. The metal zero-level layers 202 are isolated from each other by a via0-level interlayer dielectric (ILD) film 201. The first liner layer 203 covers the top surfaces of metal zero-level layer 202 and via0-level interlayer dielectric (ILD) film 201, and the first interlayer dielectric (ILD) film 204 is formed on the top surface of the first liner layer 203.

The material of the metal zero-level layer 202 comprises cobalt (Co). Due to high reactivity of Co, the first liner layer 203 requires to be rapidly deposited after the chemical-mechanical polishing (CMP) of the Co surface. The first liner layer 203 serves as a protective layer for the Co to reduce oxidation and material loss.

In embodiment of the present application, the first liner layer 203 is made of silicon nitride (SiN). In other embodiments, first liner layer 203 may also be made of silicon carbide (SiC).

In embodiment of the present application, the material of the first interlayer dielectric (ILD) film 204 includes silicon oxide or a low-k dielectric material.

The metal zero-level layer 202 is connected to the underlying semiconductor device structures such as a gate conductive layer or doped regions like a source/drain region.

Step S102: As shown in FIG. 4A, the first interlayer dielectric film 204 and the first liner layer 203 in the region for forming the via0 structure are sequentially etched to form a via0 opening 205. During the etching process of the first liner layer 203, fluorine-containing polymer 207 is generated. The plasma used in the via0 etching process forms a Co-damaged layer 202a in the surface region of the metal zero-level layer 202.

In the formation of the via0 opening 205, the etching process for the first interlayer dielectric film 204 includes a first dry etching step. This first dry etching is plasma-based and stops at first liner layer 203. Therefore, the first liner layer 203 serves as an etch stop layer in the first dry etching step, which helps to improve the uniformity of etch depth.

During the formation of via0 opening 205, the etching process for the first interlayer dielectric film 204 further includes performing a second wet etching after completing the first dry etching.

In the formation of the via0 opening 205, the etching process for the first liner layer 203 is a liner removal process. The etching of the first liner layer 203 includes a second dry etching, which is indicated by dashed arrow 206 in FIG. 4A. The second dry etching is also plasma-based, and process gas used in the second dry etching comprises fluorine-containing gas.

In some embodiments, fluorine-containing gas includes difluoromethane (CH₂₂).

The process gas for second dry etching may further include oxygen (O₂) or nitrogen (N₂).

Since the fluorine-containing gas is used in second dry etching, fluorine-containing polymer 207 is finally formed.

Meanwhile, since etching process for via0 opening 205 comprises multiple etching steps, plasma etching is employed in multi-step etching process. For example, plasma is used in the first dry etching and the second dry etching. The bombardment effect of the plasma can damage the surface region of the metal zero-level layer 202, resulting in the formation of the Co-damaged layer 202a.

Step S103: As shown in FIG. 4B, the first wet cleaning is performed to remove the Co-damaged layer 202a in metal zero-level layer 202. In first wet cleaning process, fluorine (F) retained in the fluorine-containing polymer 207 is utilized to enhance the removal of the Co-damaged layer 202a, thereby effectively eliminating the Co-damaged layer 202a.

In embodiment of present application, cleaning solution used in the first wet cleaning is deionized (DI) solution. The fluorine (F) in the fluorine-containing polymer 207 reacts with the DI solution to generate HF, which can effectively remove the Co-damaged layer 202a. It is necessary to completely etch away Co-damaged layer 202a as much as possible to avoid the formation of Co residue defects in subsequent processes.

In the embodiment of the present application, since fluorine-containing polymer 207 is not removed prior to the first wet cleaning, a sufficient concentration of HF can be ensured, thereby enhancing the removal efficiency of the Co-damaged layer 202a.

In conventional methods, if the fluorine-containing polymer is removed prior to DI cleaning, the concentration of HF generated will be insufficient to remove Co-damaged layer. As a result, Co residue defects are likely to form.

Step S104: As shown in FIG. 4C, the second wet cleaning is performed to remove the fluorine-containing polymer 207. By taking advantage of the fact that Co-damaged layer 202a has already been removed in the previous step, this second wet cleaning step prevents the formation of Co residue defects.

In the embodiment of the present application, cleaning solution used for the second wet cleaning is a mildly alkaline solution containing the Co inhibitor. Preferably, the cleaning solution used in this step is a proprietary solution labeled C1000, developed by the applicant.

The C1000 solution ensures effective removal of fluorine-containing polymer 207. Meanwhile, since the C1000 solution does not etch or degrade the undamaged, i.e., fresh Co layer, it does not cause any Co residue to be released, thereby preventing the formation of Co residue defects.

In embodiment of the present application, because C1000 solution does not damage fresh Co layer, the second wet cleaning can be repeated multiple times. In some embodiments, the second wet cleaning is repeated twice.

By repeating the second wet cleaning step multiple times, complete removal of the fluorine-containing polymer 207 can be ensured, along with newly generated residues from first wet cleaning. This approach effectively reduces defect sites that could lead to selectivity loss during subsequent tungsten selective growth process, thereby minimizing the root causes of tungsten missing defects.

In addition, in the embodiment of present application, the first wet cleaning step itself does not pose a risk of selectivity loss.

In some embodiments, after completing second wet cleaning and before performing the subsequent tungsten selective growth, the method further includes:
a pre-treatment with an alkaline solution, namely an OH pre-treatment.

Step S105: As shown in FIG. 4D, selective tungsten growth is performed to deposit a tungsten layer 209 from the bottom surface of the via0 opening 205 upward, thereby filling the via0 opening 205 and forming a via0 structure composed of the tungsten layer 209.

The selective tungsten growth occurs only on metallic surfaces. In the embodiment of the present application, since the metal is located only at the bottom of the via0 opening 205, tungsten is deposited from bottom upward. This allows for complete filling of via0 opening 205 without requiring an adhesion/barrier layer or a seed layer. Furthermore, because cobalt residue defects have been eliminated, no tungsten growth occurs on side surfaces or external surfaces of the via0 opening 205. As a result, via0 opening 205 remains open at top during selective tungsten growth process, preventing the formation of voids within the via0 opening 205 and thereby avoiding tungsten loss defects.

In embodiment of present application, after selective tungsten growth is completed,
a tungsten chemical-mechanical polishing (CMP) process is performed to planarize the tungsten layer 209.

In the embodiment of the present application, this process utilizes the fact that both fluorine-containing polymer 207 and Co-damaged layer 202a are simultaneously generated during formation of the via0 opening 205. Unlike the prior art, in which the cleaning process to remove fluorine-containing polymer 207 is performed first, followed by cleaning process to remove Co damaged layer 202a, the present application reverses the sequence. Specifically, the cleaning process for removing the Co damaged layer 202a, i.e., the first wet cleaning, is performed first. At this stage, since fluorine-containing polymer 207 has not been removed, the fluorine (F) contained in the polymer 207 enhances the removal of the Co-damaged layer 202a. After the Co-damaged layer 202a is removed, the cleaning process for removing the fluorine-containing polymer 207, i.e., second wet cleaning, is then carried out. The second wet cleaning can completely remove fluorine-containing polymer 207. Meanwhile, because the Co-damaged layer 202a has already been removed, and the second wet cleaning does not affect the undamaged or fresh Co layer, no Co residue defects are formed during the second wet cleaning. That is, Co residue defects will not form on the side surfaces or outer surfaces of via0 opening 205. As a result, during the subsequent selective tungsten growth, tungsten layer 209 can reliably grow upward from the top surface of the metal zero-level layer 202 exposed at bottom of via0 opening 205. This prevents the tungsten layer 209 from nucleating on Co residue defects in other regions, which would otherwise lead to top closure of the via0 opening 205 or tungsten loss defects on right side. Thus, tungsten layer 209 can completely fill via0 opening 205 from bottom up, forming a high-quality via0 structure. Ultimately, this improves device performance and manufacturing yield.

The above detailed description of the present application is provided through specific embodiments, but it should not be construed as limiting the scope of the invention. Various modifications and improvements can be made by those skilled in the art without departing from principles of the present application, and such modifications and improvements should also be regarded as falling within the scope of the present application.

What is claimed is:

1. A method for manufacturing a via0 structure, comprising the following steps:
providing a bottom structure comprising a metal zero-level layer, a first liner layer as well as a first interlayer dielectric (ILD) film, wherein the metal zero-level layers are isolated from each other by via0 ILD film, the first liner layer covers top surfaces of both the metal zero-level layer and the via0 ILD film, and the first ILD film is formed on a top surface of the first liner layer; wherein a material of the metal zero-level layer comprises cobalt;
etching the first ILD film and the first liner layer in a via0 formation region to form a via0 opening, wherein etching of the first liner layer generates a fluorine-containing polymer, and plasma used during the etching causes a cobalt damage layer to form on a surface region of the metal zero-level layer;
performing a first wet cleaning to remove cobalt damage layer in the metal zero-level layer, wherein a fluorine remaining in the fluorine-containing polymer is utilized to enhance removal of the cobalt damage layer;
performing a second wet cleaning to remove fluorine-containing polymer, wherein the cobalt damage layer has been previously removed, thereby preventing formation of cobalt residue defects during the second wet cleaning; and
performing selective tungsten growth to deposit a tungsten layer from a bottom surface of the via0 opening upward, such that the tungsten layer fills the via0 opening to form the via0 structure.

2. The method for manufacturing the via0 structure according to claim 1, wherein a material of the first liner layer comprises silicon nitride or silicon carbide.

3. The method for manufacturing the via0 structure according to claim 1, wherein a material of the first interlayer dielectric film comprises silicon oxide or a low-k dielectric material.

4. The method for manufacturing the via0 structure according to claim 3, wherein the etching the first interlayer dielectric film to form the via0 opening comprises a first dry etching process.

5. The method for manufacturing the via0 structure according to claim 4, wherein the etching the first interlayer dielectric film further comprises performing a second wet etching process after the first dry etching process is completed.

6. The method for manufacturing the via0 structure according to claim 2, wherein the etching the first liner layer to form the via0 opening comprises a second dry etching process; and a process gas used in the second dry etching process comprises a fluorine-containing gas.

7. The method for manufacturing the via0 structure according to claim 6, wherein the process gas used in the second dry etching process further comprises oxygen or nitrogen.

8. The method for manufacturing the via0 structure according to claim 6, wherein the fluorine-containing gas comprises difluoromethane.

9. The method for manufacturing the via0 structure according to claim 1, wherein a deionized solution is used as a cleaning solution in the first wet cleaning.

10. The method for manufacturing the via0 structure according to claim 1, wherein a cleaning solution used in second wet cleaning comprises a cobalt inhibitor and is weakly alkaline.

11. The method for manufacturing the via0 structure according to claim 10, wherein the second wet cleaning is performed multiple times.

12. The method for manufacturing the via0 structure according to claim 11, wherein the second wet cleaning is performed twice.

13. The method for manufacturing the via0 structure according to claim 1, wherein, after the second wet cleaning is completed and before the selective tungsten growth is performed, the method further comprises:
performing a pretreatment using an alkaline solution.

14. The method for manufacturing the via0 structure according to claim 1, wherein, after the selective tungsten growth is completed, the method further comprises:
performing a tungsten chemical-mechanical polishing process to planarize the tungsten layer.
